(19) United States
(12) Patent Application Publication
(10) Pub. No.: US 2024/0063189 A1
(43) Pub. Date: Feb. 22, 2024

(54) STACKED LONG CHANNEL TRANSISTOR

(71) Applicant: INTERNATIONAL BUSINESS MACHINES CORPORATION, ARMONK, NY (US)

(72) Inventors: Heng Wu, Santa Clara, CA (US); Ruilong Xie, Niskayuna, NY (US); Julien Frougier, Albany, NY (US); Min Gyu Sung, Latham, NY (US); Nicolas Jean Loubet, GUILDERLAND, NY (US)

(21) Appl. No.: 17/820,264

(22) Filed: Aug. 17, 2022

(51) Int. Cl. H01L 25/07; H01L 21/822; H01L 21/84; H01L 27/12; H01L 27/06; H01L 29/786

(52) U.S. Cl. CPC H01L 25/074; H01L 21/8221; H01L 21/845; H01L 27/1211; H01L 27/0688; H01L 29/78696

(57) ABSTRACT

A long channel transistor structure including a first transistor array adjacent to a second transistor array, a third transistor array adjacent to a fourth transistor array, where the third transistor array and the fourth transistor array are arranged above the first transistor array and the second transistor array, and a continuous channel path through channels of the first transistor array, the second transistor array, the third transistor array, and the fourth transistor array.

### BACKGROUND

The present invention generally relates to semiconductor structures, and more particularly to stacked long channel transistor structures.

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node. A potential solution to this chip scaling problem is stacked transistor technology.

### SUMMARY

According to an embodiment of the present invention, a semiconductor structure is provided. The semiconductor structure may include a first transistor array adjacent to a second transistor array, a third transistor array adjacent to a fourth transistor array, where the third transistor array and the fourth transistor array are arranged above the first transistor array and the second transistor array, and a continuous channel path through channels of the first transistor array, the second transistor array, the third transistor array, and the fourth transistor array.

According to another embodiment of the present invention, a semiconductor structure is provided. The semiconductor structure may include a first transistor array adjacent to a second transistor array, a third transistor array adjacent to a fourth transistor array, where the third transistor array and the fourth transistor array are arranged above the first transistor array and the second transistor array, and interconnect structures forming a continuous electrical path through channels of the first transistor array, the second transistor array, the third transistor array, and the fourth transistor array.

According to another embodiment of the present invention, a semiconductor structure is provided. The semiconductor structure may include a first transistor array including a first series of short channel devices and a first continuous channel, a second transistor array including a second series of short channel devices and a second continuous channel, and a vertical interconnect structure electrically connecting the first continuous channel to the second continuous channel.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a representative illustration of a top view of a structure shown during an intermediate step of a method of fabricating a stacked transistor structure according to an embodiment of the invention;

FIGS. 2 and 3 are cross-sectional views of the semiconductor structure depicted in FIG. 1 during an intermediate step of a method of fabricating a stacked transistor structure according to an exemplary embodiment;

FIG. 4 is a representative illustration of a top view of the structure after forming a horizontal strap interconnect in a first dielectric layer according to an exemplary embodiment;

FIGS. 5 and 6 are cross-sectional views of the structure depicted in FIG. 4 according to an exemplary embodiment;

FIG. 7 is a representative illustration of a top view of the structure after forming a third transistor array and a fourth transistor array formed above the first transistor array and the second transistor array according to an exemplary embodiment;

FIGS. 8 and 9 are cross-sectional views of the structure depicted in FIG. 7 according to an exemplary embodiment;

FIG. 10 is a representative illustration of a top view of the structure after forming a first vertical strap interconnect, a second vertical strap interconnect, a first source drain contact, and a second source drain contact in a second dielectric layer according to an exemplary embodiment;

FIGS. 11, 12 and 13 are cross-sectional views of the structure depicted in FIG. 10 according to an exemplary embodiment;

FIG. 14 is a representative illustration of an alternative structure according to an alternative embodiment of the invention;

FIG. 15 is a representative illustration of an alternative structure according to an alternative embodiment of the invention; and

FIG. 16 is a representative illustration of an alternative structure according to an alternative embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, or stacked transistors, have known advantages over conventional transistor structures in terms of density, performance, power consumption, and integration. Currently forming long channel devices is difficult due to the high-density nature of the stacked transistors. For example, long channel nanosheet devices are particularly challenging to fabricate due to the high probability the nanosheets will collapse during fabrication.

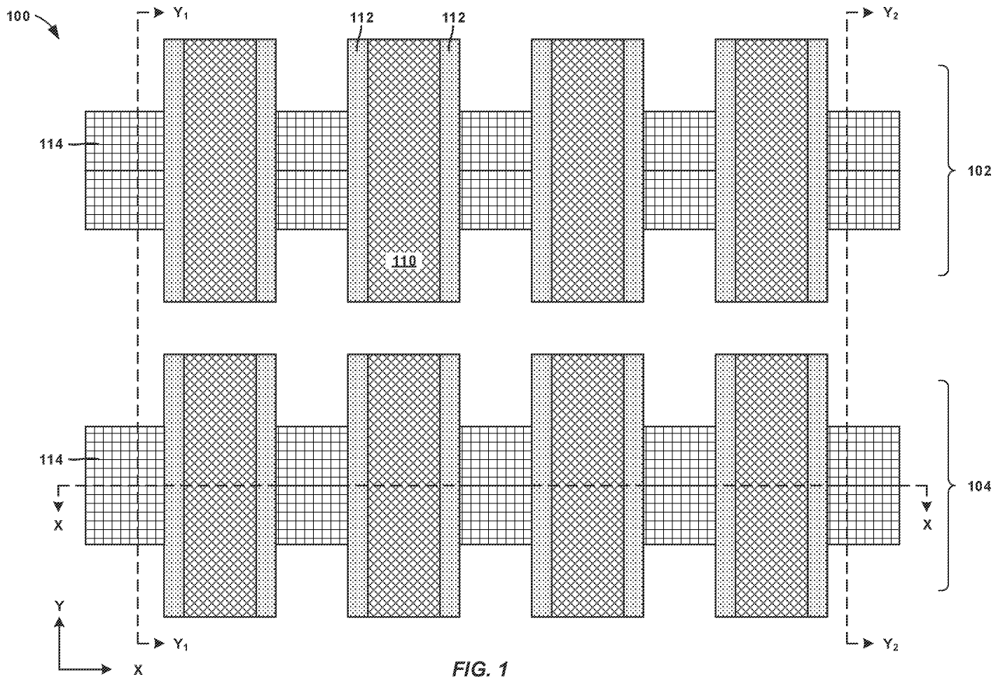

The present invention generally relates to semiconductor structures, and more particularly to stacked long channel transistor structures. More specifically, the stacked long channel transistor structures and associated methods disclosed herein enable a novel solution for fabricating long channel devices in a very dense stacked configuration. Exemplary embodiments of stacked long channel transistor structures arranged in a stacked configuration are described in detail below by referring to the accompanying drawings in FIGS. 1 to 16. Those skilled in the art will readily appreciate that the detailed description given herein with respect to these figures is for explanatory purposes as the invention extends beyond these limited embodiments.

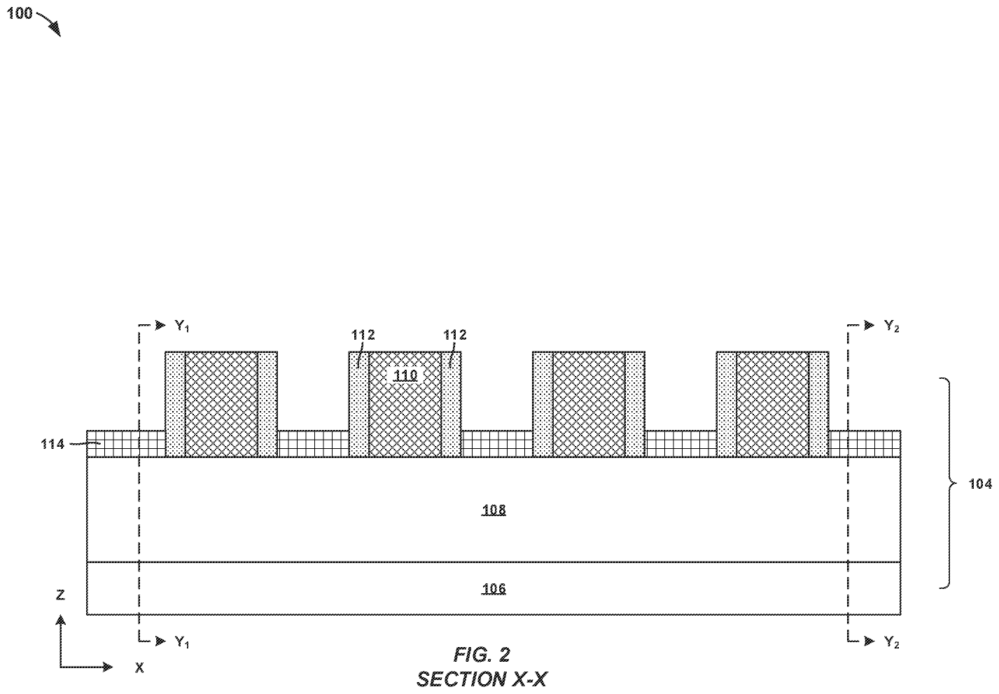

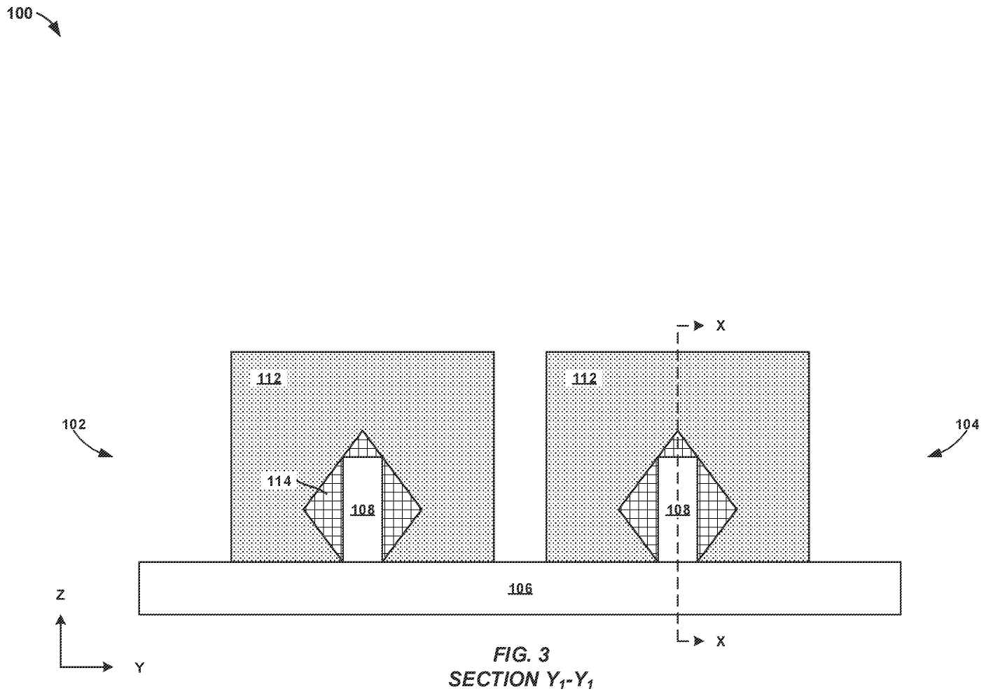

Referring now to FIGS. 1, 2, and 3, a structure 100 is shown during an intermediate step of a method of fabricating a stacked long channel transistor structure according to an embodiment of the invention. FIG. 1 is a representative illustration of a top view of the structure 100 omitting some materials and layers, for example, patterning layers, masking layers and interlevel dielectrics. As such, only pertinent layers and components are shown to provide a clear understanding of their relative orientation. FIG. 2 depicts a cross-sectional view of the structure 100 shown in FIG. 1 taken along line X-X. FIG. 3 depicts a cross-sectional view of the structure 100 shown in FIG. 1 taken along line Y₁-Y₁.

The structure 100 illustrated in FIGS. 1-3 includes a first transistor array 102 and a second transistor array 104 formed on a substrate 106 in accordance with known techniques. The substrate 106 may include a bulk semiconductor or a layered semiconductor such as Si/SiGe, a silicon-on-insulator (all), or a SiGe-on-insulator (SGOI). As illustrated, each transistor array 102, 104 includes a fin 108 and a series of gate conductors 110, gate spacers 112 according to known structures and techniques. After forming the gate conductors 110, gate spacers 112, exposed portions of the fins 108 are covered with epitaxial regions 114 according to known techniques.

As understood by persons having ordinary skill in the art, portions of the fin 108 directly beneath each gate conductor 110 will function, and hereinafter be referred to as a channel. In general, individual transistors of each transistor array 102, 104 may have a relatively short channel length and thus be referred to as short-channel devices. For example, a channel length of the individual transistors may range from about 12 nm to about 15 nm.

As described herein, the channel length refers to a length of the channel directly beneath each individual gate conductor (110), and each transistor array of the illustrated embodiment, has a cumulative channel length four times the channel length of any one individual transistor. It is further noted, each transistor array (102, 104) of the illustrated embodiment includes four transistor structures; however, they will not be wired to operate as individual transistor structures as described in more detail below.

Although only a limited number of components, devices, or structures are shown, embodiments of the present invention shall not be limited by any quantity otherwise illustrated or discussed herein.

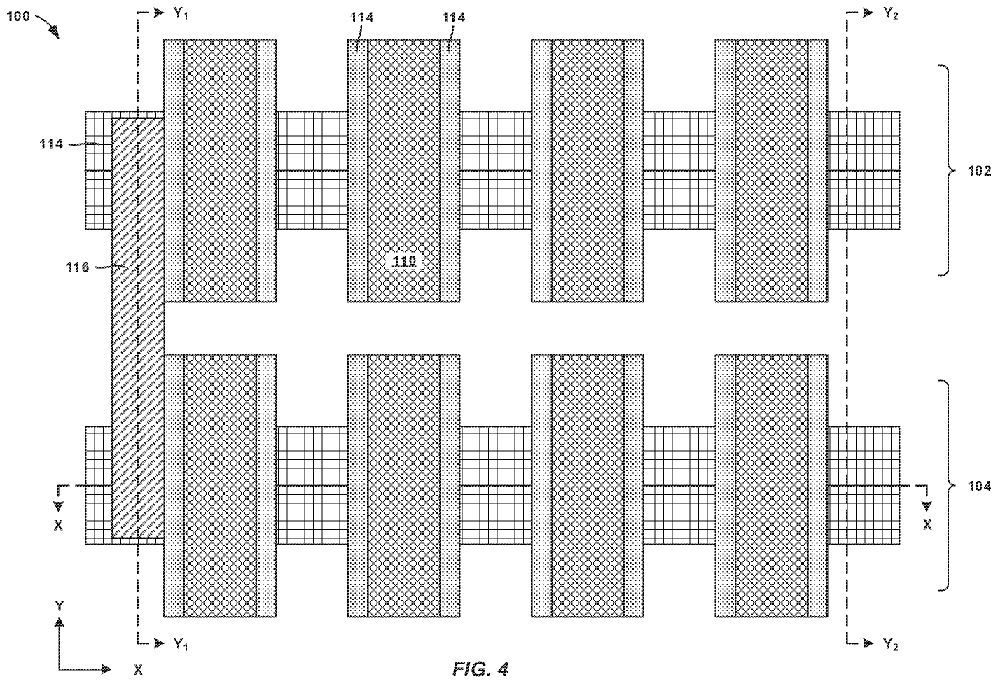

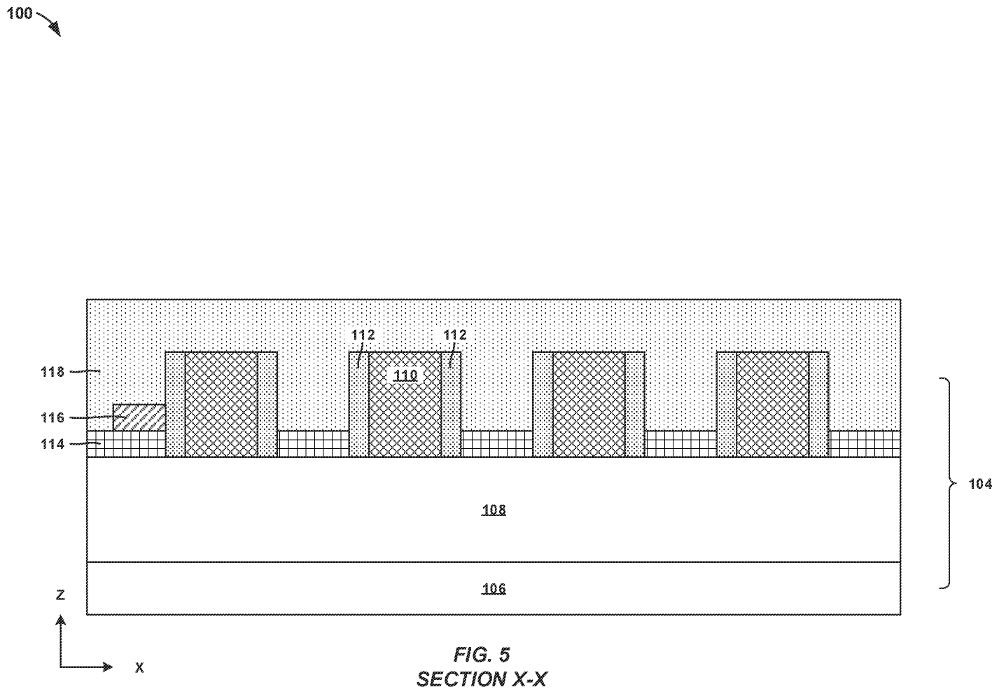

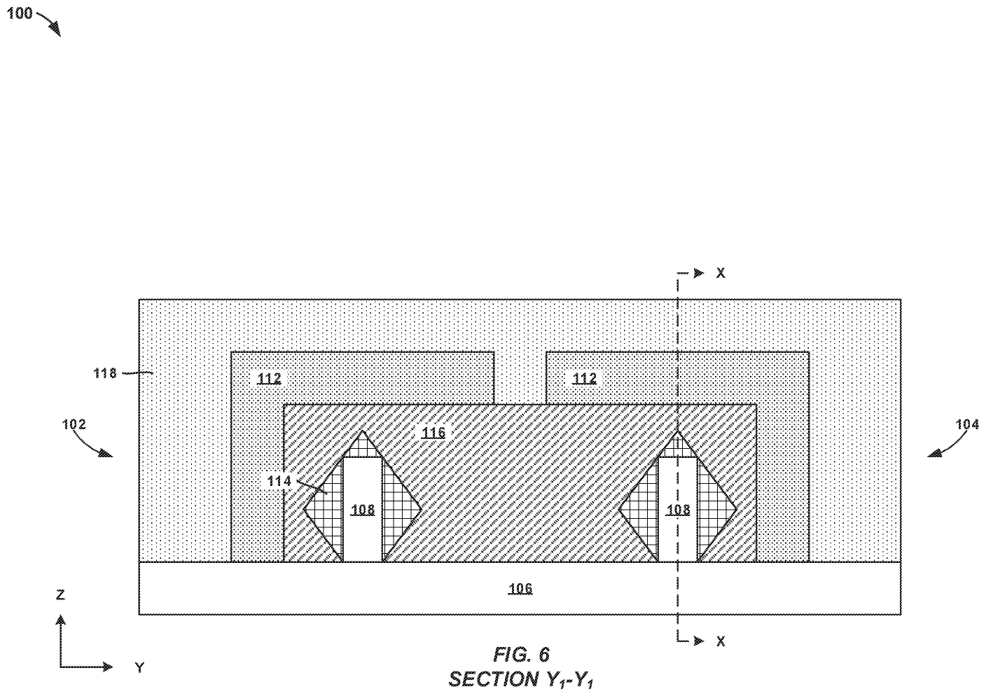

Referring now to FIGS. 4, 5, and 6, a structure 100 is shown after forming a horizontal strap interconnect 116 in a first dielectric layer 118 according to an embodiment of the invention. FIG. 4 is a representative illustration of a top view of the structure 100 omitting some features as described above with reference to FIG. 1. FIG. 5 depicts a cross-sectional view of the structure 100 shown in FIG. 4 taken along line X-X. FIG. 6 depicts a cross-sectional view of the structure 100 shown in FIG. 4 taken along line Y₁-Y₁.

First, the first dielectric layer 118 is blanket deposited across the entire structure 100. It is noted, the first dielectric layer 118, as illustrated in FIGS. 4, 5, and 6 may be deposited in multiple steps according to known techniques. In a typical fashion, the first dielectric layer 118 may be any known dielectric materials such as, for example, silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than silicon dioxide. In another embodiment, a self-planarizing material such as a spin-on glass (SOG) or a spin-on low-k dielectric material such as SiLK™ can be used as the first dielectric layer 118. The use of a self-planarizing dielectric material as the first dielectric layer 118 may avoid the need to perform a subsequent planarizing step.

Next, a first interconnect trench (not shown) is formed using conventional lithography and etching in the first dielectric layer 118 exposing portions of the epitaxial regions 114 of both the first transistor array 102 and the second transistor array 104. Specifically, in the illustrated embodiment, etching the first interconnect trench is performed selective to the gate spacers 112 and both the epitaxial regions 114 and thus does not remove any significant portion of the epitaxial regions 114. In the present example, the portions of the epitaxial regions 114 exposed by the first interconnect trench are at common ends of both the first transistor array 102 and the second transistor array 104.

Finally, the horizontal strap interconnect 116 is formed within the first interconnect trench according to known techniques. For example, the first interconnect trench may be filled or partially filled with a suitable conductive material, such as, silicide liner such as Ti, Ni. or NiPt and adhesion metal liner such as TiN and conductive metal such as tungsten, copper, or titanium using known depositions techniques. In some embodiments, an uppermost surface of the horizontal strap interconnect 116 are recessed below top surfaces of the gate conductors 110, and in other embodiments, the uppermost surface of the horizontal strap interconnect 116 is flush, or substantially flush, with the top surfaces of the gate conductors 110. Various configurations for horizontal strap interconnect 116 are possible and can be implemented according to known techniques.

Critical to the present invention, the horizontal strap interconnect 116 forms an electrical connection between the fin 108 of the first transistor array 102 and the fin 108 of the second transistor array 104, as illustrated. In the present embodiment, the horizontal strap interconnect 116 directly contacts the epitaxial regions 114; however, doing so is not absolutely necessary. For example, in at least one embodiment, the horizontal strap interconnect 116 can be formed in direct contact with the fins 108 (channels) prior to forming the epitaxial regions 114. Alternatively, portions of the epitaxial regions 114 can be recessed or removed prior to forming the horizontal strap interconnect 116, and allow the horizontal strap interconnect 116 to be deposited direct contact with the fins 108 according to known techniques.

Finally, the horizontal strap interconnect 116 of the present invention is self-aligned to the end-most gate spacers 112 of each transistor array 102, 104. Doing so conserves space; however, is not completely necessary.

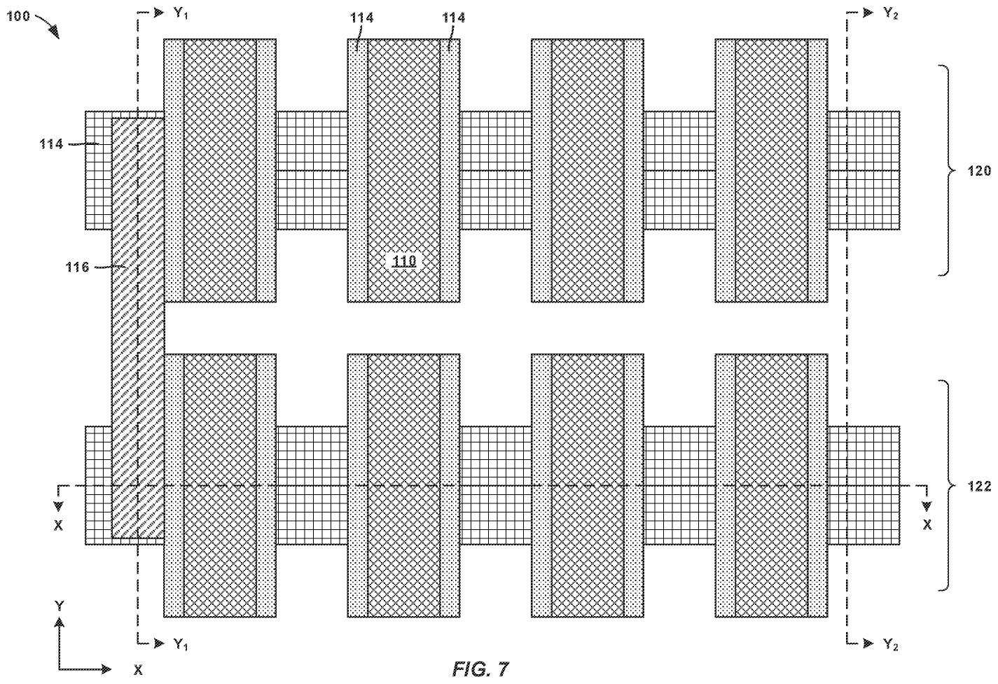

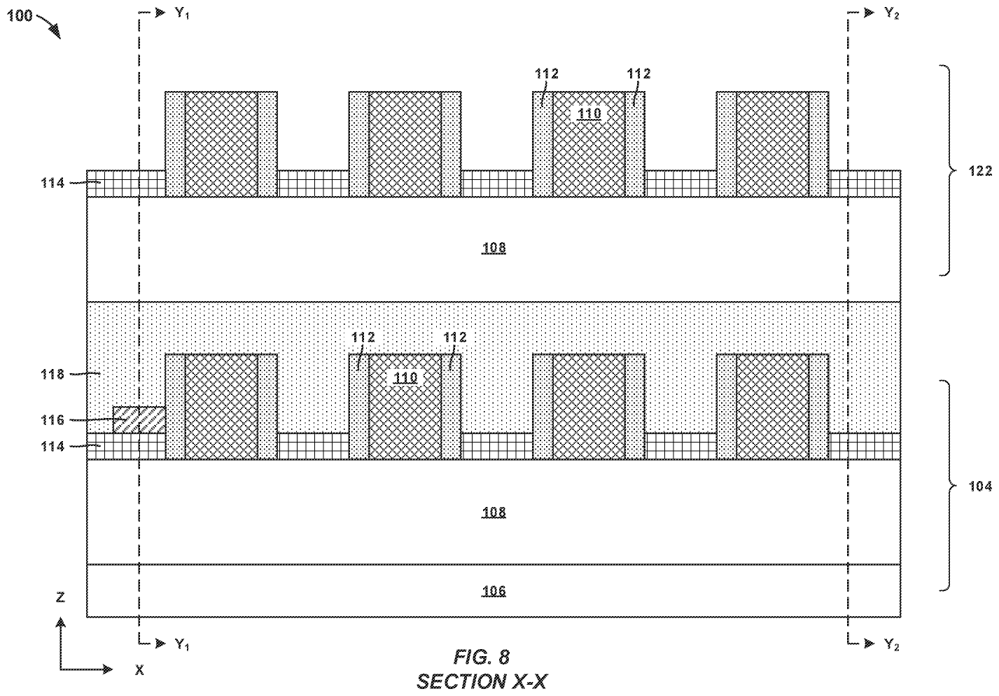

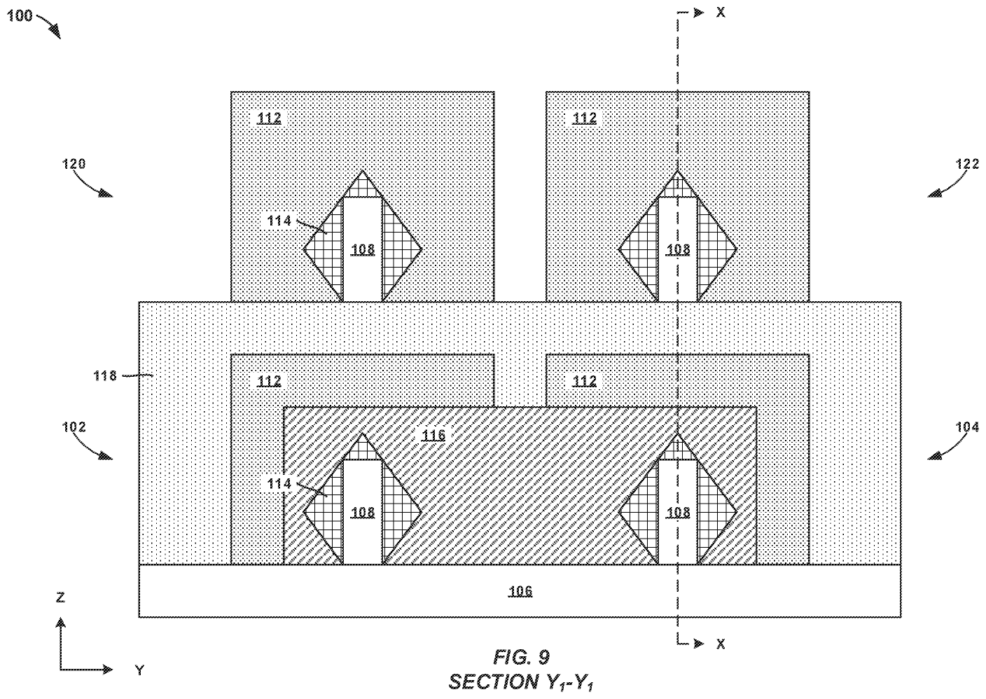

Referring now to FIGS. 7, 8, and 9, a structure 100 is shown after forming a third transistor array 120 and a fourth transistor array 122 formed above the first transistor array 102 and the second transistor array 104 according to an embodiment of the invention. FIG. 7 is a representative illustration of a top view of the structure 100 omitting some features as described above with reference to FIG. 1. FIG. 8 depicts a cross-sectional view of the structure 100 shown in FIG. 7 taken along line X-X. FIG. 9 depicts a cross-sectional view of the structure 100 shown in FIG. 7 taken along line Y₁-Y₁.

The third transistor array 120 and the fourth transistor array 122 are fabricated directly above the first transistor array 102 and the second transistor array 104 according to known techniques used in forming stacked transistors. According to an embodiment, the third transistor array 120 is aligned directly above the first transistor array 102 and the fourth transistor array 122 is aligned directly above the second transistor array 104 as illustrated. Alternative embodiments in which the stacked transistor arrays are not directly atop one another are explicitly contemplated. For example, some misalignment may occur as a result of conventional fabrication techniques. Alternatively, the stacked transistor arrays may be offset from one another. For example, the third transistor array 120 and the fourth transistor array 122 can be offset in the y-direction from the first transistor array 102 and the second transistor array 104.

In general, the third transistor array 120 and the fourth transistor array 122 are the same, or substantially similar to, the first transistor array 102 and the second transistor array 104 described above. Specifically, the third transistor array 120 and the fourth transistor array 122 each also include a fin 108, a series of gate conductors 110, gate spacers 112, and epitaxial regions 114 according to known techniques.

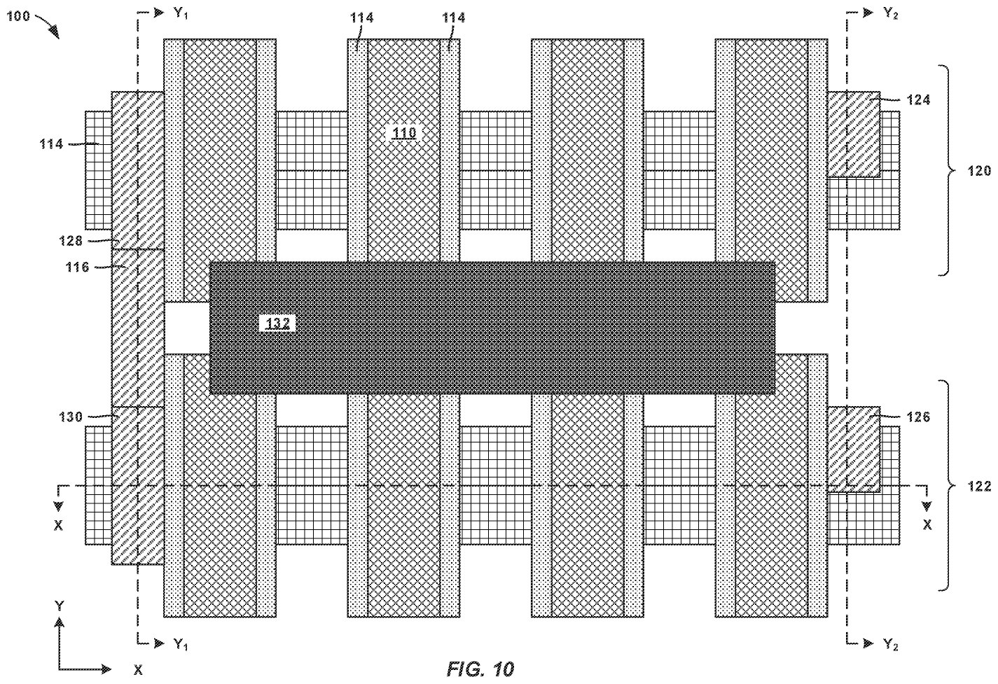

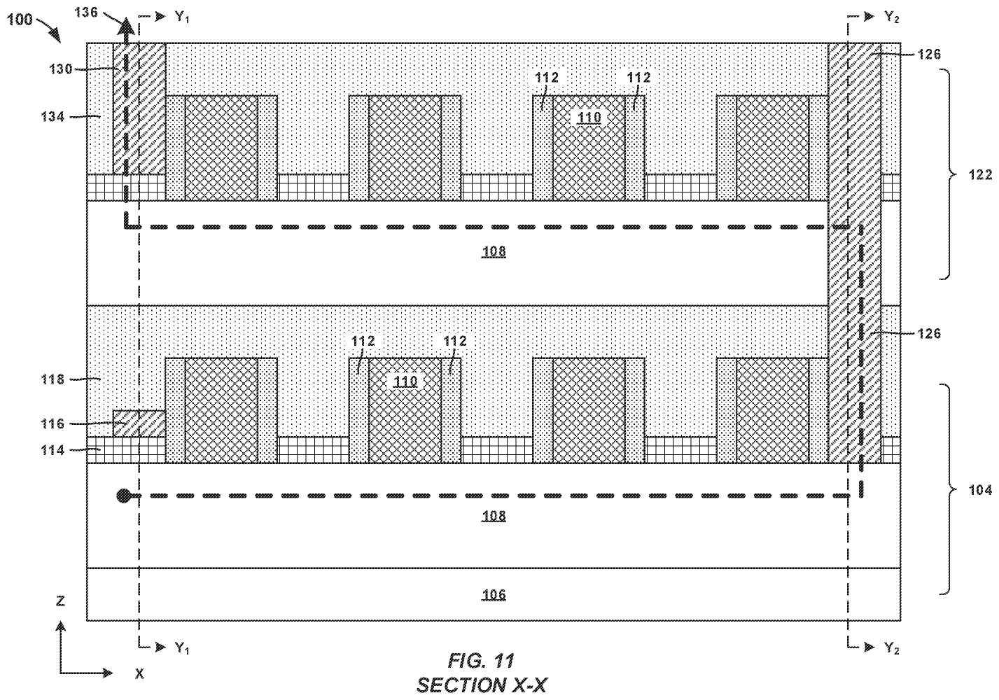

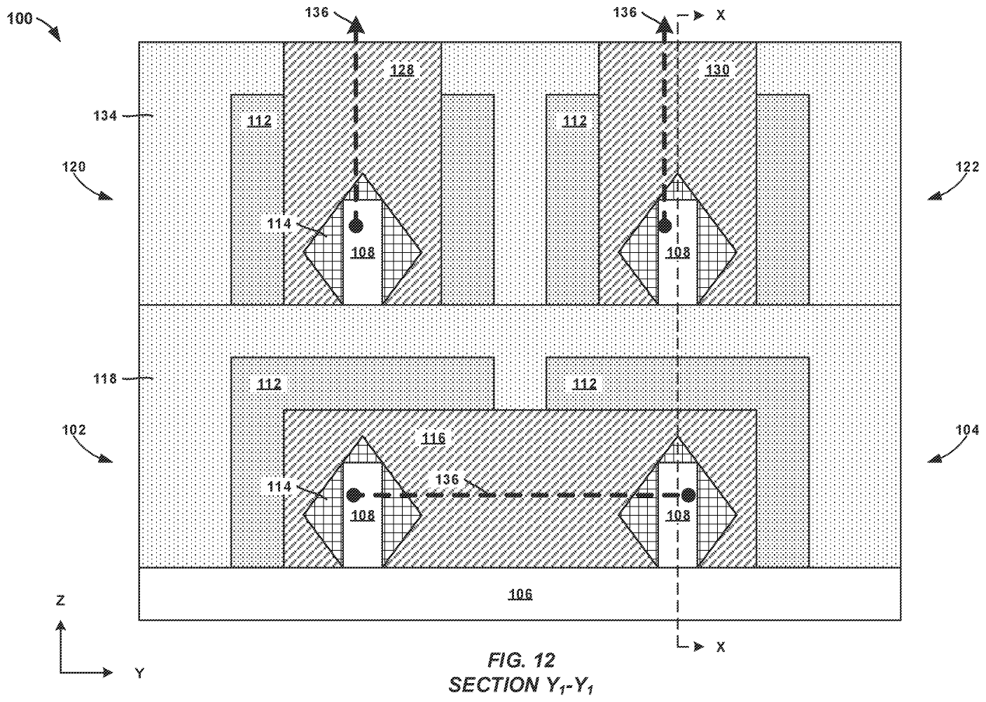

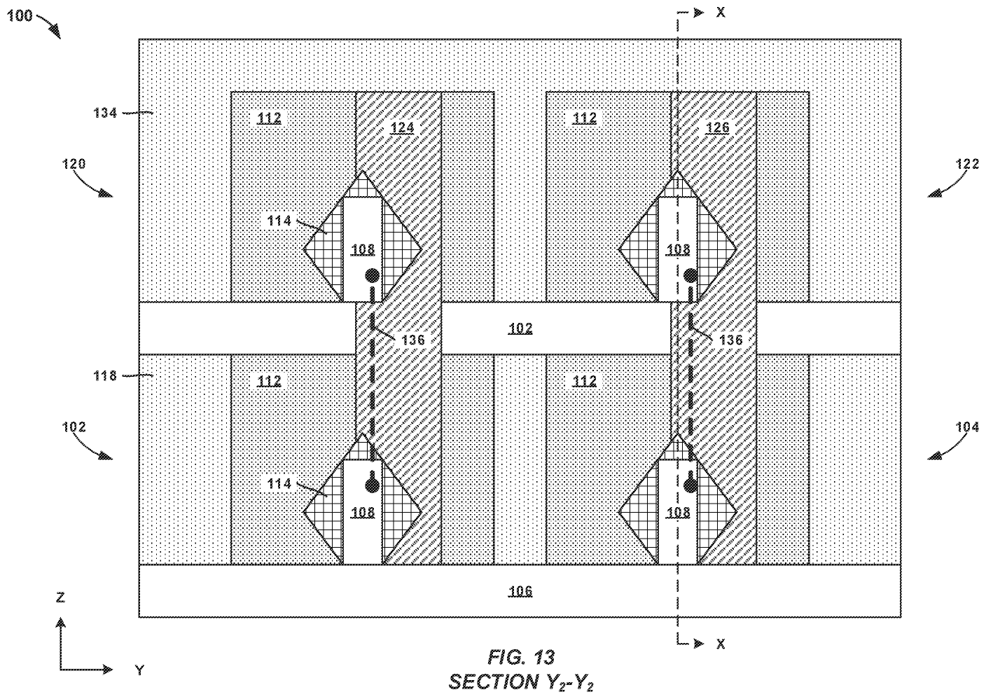

Referring now to FIGS. 10, 11, 12, and 13, a structure 100 is shown after forming a first vertical strap interconnect 124, a second vertical strap interconnect 126, a first source drain contact 128, a second source drain contact 130 and a shared gate contact 132 in a second dielectric layer 134 according to an embodiment of the invention. FIG. 10 is a representative illustration of a top view of the structure 100 omitting some features as described above with reference to FIG. 1. FIG. 11 depicts a cross-sectional view of the structure 100 shown in FIG. 10 taken along line X-X. FIG. 12 depicts a cross-sectional view of the structure 100 shown in FIG. 10 taken along line Y₁-Y₁. FIG. 13 depicts a cross-sectional view of the structure 100 shown in FIG. 10 taken along line Y₂-Y₂.

First, the second dielectric layer 134 is blanket deposited across the entire structure 100. It is noted, the second dielectric layer 134, as illustrated in FIGS. 10, 11, 12, and 13 may be deposited in multiple steps according to known techniques. According to embodiments descried herein, the second dielectric layer 134 may be similar, or substantially similar, to the first dielectric layer 118 described above.

Also like above, additional interconnect trenches (not shown) are formed. For example, a second interconnect trench and a third interconnect trench are formed in both the first dielectric layer 118 and the second dielectric layer 134 exposing portions of the epitaxial regions 114 and the fins 108 of the first transistor array 102, the second transistor array 104, the third transistor array 104 and the fourth transistor array 122. Specifically, in the illustrated embodiment, etching the second and third interconnect trenches is performed selective to the gate spacers 112 but without selectivity to the epitaxial regions 114. Doing so is designed to remove portions of the epitaxial regions 114 as well as portions of the fins 108, as illustrated. As such, sidewall portions of both the epitaxial regions 114 and the fins 108 will be exposed after forming the second and third interconnect trenches. Further, the second and third interconnect trenches are positioned at opposite ends of the transistor arrays from the horizontal strap interconnect 116.

Next, the second and third interconnect trenches are filled with a suitable conductive material to form the first vertical strap interconnect 124 and the second vertical strap interconnect 126 according to known techniques.

Additionally, a fourth interconnect trench and a fifth interconnect trench are formed in the second dielectric layer 134 exposing portions of the epitaxial regions 114 of the third transistor array 104 and the fourth transistor array 122. The fourth and fifth interconnect trenches are positioned at the same ends of the transistor arrays as the horizontal strap interconnect 116. It is further noted, the fourth and fifth interconnect trenches stop at, or about, the epitaxial regions 114 of the third transistor array 104 and the fourth transistor array 122. Therefore, like the first interconnect trench described above, etching the fourth and fifth interconnect trenches is performed selective to the epitaxial regions 114 and thus does not remove any significant portion of the epitaxial regions 114. In contrast, the second and third interconnect trenches, described above, extend all the way down to the first transistor array 102 and the second transistor array 104.

Next, the fourth and fifth interconnect trenches are filled with a suitable conductive material to form the first source drain contact 128 and the second source drain contact 130 according to known techniques.

In general, because of the different depths, the vertical strap interconnects 124, 126 are formed at different times using different masks and different etch chemistries than the source drain contacts 128, 130. Although the vertical strap interconnects 124, 126 and the source drain contacts 128, 130 are formed at different times, the order in which they are formed is not important.

As illustrated, the uppermost surfaces of the vertical strap interconnects 124, 126 and the uppermost surfaces of the source drain contacts 128, 130 are flush, or substantially flush, with one another. In an embodiment, the uppermost surfaces of the vertical strap interconnects 124, 126 and the source drain contacts 128, 130 are not flush and some may be higher or lower than others depending on the order and the manner in which they are formed. In some embodiments, uppermost surfaces of the vertical strap interconnects 124, 126 and the source drain contacts 128, 130 are above top surfaces of the gate conductors 110. In other embodiments, uppermost surfaces of the vertical strap interconnects 124, 126 and the source drain contacts 128, 130 are flush, or substantially flush, with top surfaces of the gate conductors 110.

In embodiments where the stacked transistor arrays are offset from one another, as previously discussed, the first vertical strap interconnect 124 and the second vertical strap interconnect 126 would take a different shape. For example, the first vertical strap interconnect 124 and the second vertical strap interconnect 126 could be fabricated wider, in the y-direction, to ensure contact between stacked transistor arrays.

Critical to the present invention, the first vertical strap interconnect 124 and the second vertical strap interconnect 126 form electrical connections between corresponding stacked transistor arrays. Specifically, the first vertical strap interconnect 124 forms an electrical connection between the fin 108 of the first transistor array 102 and the fin 108 of the third transistor array 120, and second vertical strap interconnect 126 forms an electrical connection between the fin 108 of the second transistor array 104 and the fin 108 of the fourth transistor array 122, as illustrated. In contrast, the first source drain contact 128 and the second source drain contact 130 do not form electrical connection between adjacent transistor arrays but instead provide external contacts for the stacked long channel transistor structure 100.

In the present embodiment, the first vertical strap interconnect 124, the second vertical strap interconnect 126, the first source drain contact 128, and the second source drain contact 130 each directly contact respective epitaxial regions 114; however, doing so is not absolutely necessary. For example, in at least one embodiment, the first vertical strap interconnect 124, the second vertical strap interconnect 126, the first source drain contact 128, and the second source drain contact 130 can be formed in direct contact with the fins 108 (channels) prior to forming the epitaxial regions 114. Alternatively, portions of the epitaxial regions 114 or the fins 108, or both can be recessed or removed prior to forming the first vertical strap interconnect 124, the second vertical strap interconnect 126, the first source drain contact 128, and the second source drain contact 130.

The first vertical strap interconnect 124, the second vertical strap interconnect 126, the first source drain contact 128, and the second source drain contact 130 are all self-aligned to the end-most gate spacers 112 of each transistor array (102, 104, 120, 122). Doing so conserves space; however, is not completely necessary.

Unlike conventional structures, the sixteen individual transistor structures of the four transistor arrays are wired together and operate as a single long channel device with the shared gate contact 132. The shared gate contact 132 is formed above the individual gate conductors 110 according to known techniques. The shared gate contact 132 shown in FIG. 10 is merely an example, and persons having skill in the art understand the various additional shapes, sizes, and configurations for the shared gate contact 132.

In one example, the shared gate contact 132 is formed in the second dielectric layer 134 using typical damascene techniques just like described above with respect to the vertical interconnects (124, 126) and the source drain contacts (128, 130). In such cases, a polishing technique may be applied after forming the shared gate contact 132, the vertical interconnects (124, 126) and the source drain contacts (128, 130). In another example, where the uppermost surfaces of the vertical strap interconnects 124, 126 and the source drain contacts 128, 130 are flush, or substantially flush, with top surfaces of the gate conductors 110, the shared gate contact 132, as well as other middle-of-line contacts, may be formed according to known techniques, such as, subtractive etching or damascene.

Although the illustrated configuration is believed to be the most efficient, any number of transistor arrays (102, 104, 120, 122) can be configured in any manner provided the fins are joined by corresponding interconnect structures to form a continuous channel path 136 beginning at the first source drain contact 128 and ending at the second source drain contact 130, or vice versa. In the present embodiment, the continuous channel path 136 begins and ends above the transistor arrays, at the first and second source drain contacts 128, 132. As such, future connections to the structure 100 will be formed in the middle-of-line above the transistor arrays. Additionally, the individual transistor structures of the illustrated embodiment are essentially wired in series to produce the continuous channel path 136.

In sum, for purposes of this description the structure 100 illustrated in the figures and described herein includes multiple stacked transistor structures positioned adjacent, or next, to one another, and manufactured in a process flow. Embodiments of the present invention are directed primarily at a stacked long channel transistor structure fabricated using multiple stacked transistor arrays. For example, the structure 100 illustrated in the figures and described herein includes four transistor arrays (102, 104, 120, 122), each having four individual channels beneath four individual gate conductors (110). In the present invention, the long channel is achieved by the cumulative channel length of all individual transistor structures of all four transistor arrays. As illustrated, the cumulative channel length is sixteen times the channel length of any one individual transistor structure. The cumulative channel length can be tuned by (a) adjusting channel length of individual transistor structures, (b) adjusting the number of individual transistor structures in each transistor array, or (c) adjusting the number of transistor arrays.

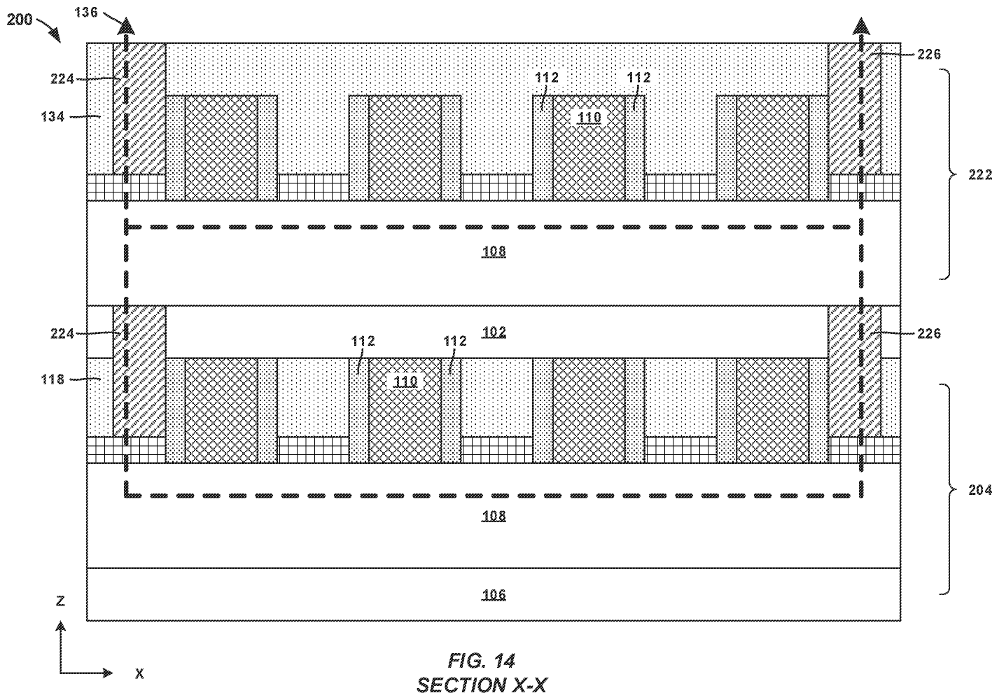

Referring now to FIG. 14, a structure 200 is shown. The structure 200 represents a stacked long channel transistor structure according to an alternative embodiment. FIG. 14 depicts a cross-sectional view taken along line X-X. The structure 200 is substantially similar to the structure 100 described above; however, the structure 200 is arranged in an alternate configuration.

For purposes of the present description, the structure 200 is illustrated and described with a first transistor array 204 and a second transistor array 222, stacked one on top of the other; however, other configurations including more transistor arrays are explicitly contemplated. For example, additional transistor arrays may be stacked vertically, or additionally transistors arrays may be arranged adjacent to the two arrays illustrated.

Unlike the structure 100, not all the individual transistor structures are wired in series. Instead, the individual transistors of each transistor array are arranged or wired in series, but the stacked transistor arrays of the structure 200 are wired in parallel. Like the first vertical strap interconnect 124 and the second vertical strap interconnect 126, the structure 200 includes a first vertical strap interconnect 224 and a second vertical strap interconnect 226 arranged at opposite ends of the transistor arrays 204, 222.

Critical to the present embodiment, the vertical strap interconnects 224, 226 form electrical connections between corresponding stacked transistor arrays 204, 222. Specifically, both the vertical strap interconnects 224, 226 form electrical connections between the fin 108 of the first transistor array 202 and the fin 108 of the second transistor array 222, as illustrated. The first vertical strap interconnect 224 is arranged at one end of the transistor arrays and the second vertical strap interconnect 226 is arrange at the opposite end of the transistor arrays. In contrast with the structure 100, the first vertical strap interconnect 224 and the second vertical strap interconnect 226 also function as source drain contacts for the structure 200.

Like the structure 100, the structure 200 also has a continuous channel path 236 that begins at the first vertical strap interconnect 224 and ends at the second vertical strap interconnect 226, or vice versa. Unique to the structure 200, the continuous channel path 236 has parallel paths through the transistor arrays.

In sum, the cumulative channel length of the structure 200 is four times the channel length of any one individual transistor structure. Unlike conventional structures, the eight individual transistor structures of the two transistor arrays are wired together with a shared gate contact and operate as a single long channel device.

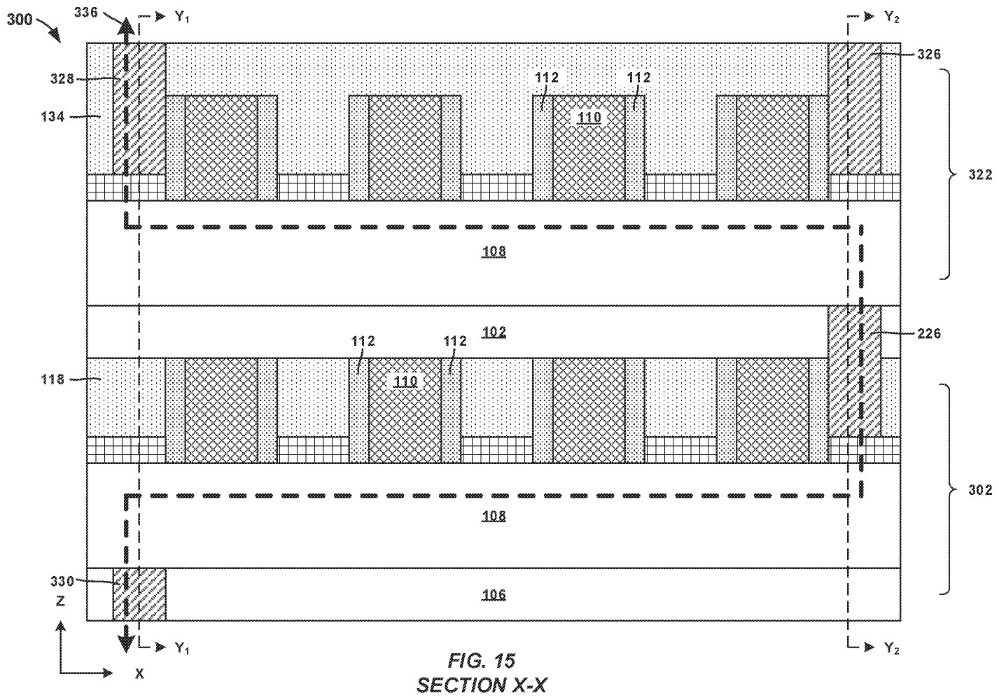

Referring now to FIG. 15, a structure 300 is shown. The structure 300 represents a stacked long channel transistor structure according to an alternative embodiment. FIG. 15 depicts a cross-sectional view taken along line X-X. The structure 300 is substantially similar to the structure 100 described above; however, the structure 300 is arranged in an alternate configuration.

For purposes of the present description, the structure 300 is illustrated and described with a first transistor array 304 and a second transistor array 322, stacked one on top of the other; however, other configurations including more transistor arrays are explicitly contemplated. For example, additional transistor arrays may be stacked vertically, or additionally transistors arrays may be arranged adjacent to the two arrays illustrated.

Like the structure 100, the structure 300 also includes a first source drain contact 328, a second source drain contact 330, and a vertical strap interconnect 326. Unlike the structure 100, the first source drain contact 328 is arranged on a top side of the structure 300 while the second source drain contact 330 is arrange on a back side of the structure 300.

Critical to the present embodiment, the vertical strap interconnects 326 forms an electrical connection between corresponding stacked transistor arrays 304, 322. Specifically, the vertical strap interconnect 326 forms an electrical connection between the fin 108 of the first transistor array 302 and the fin 108 of the second transistor array 322, as illustrated. The vertical strap interconnect 326 is arranged at one end of the transistor arrays opposite the first source drain contact 328 and the second source drain contact 330, similar to the structure 100.

Like the structure 100, the structure 300 also has a continuous channel path 336 that begins at the first source drain contact 328 and ends at the second source drain contact 330, or vice versa. The individual transistor structures of the illustrated embodiment are essentially wired in series to produce the continuous channel path 336.

In sum, the cumulative channel length of the structure 300 is eight times the channel length of any one individual transistor structure. Unlike conventional structures, the eight individual transistor structures of the two transistor arrays are wired together and operate as a single long channel device.

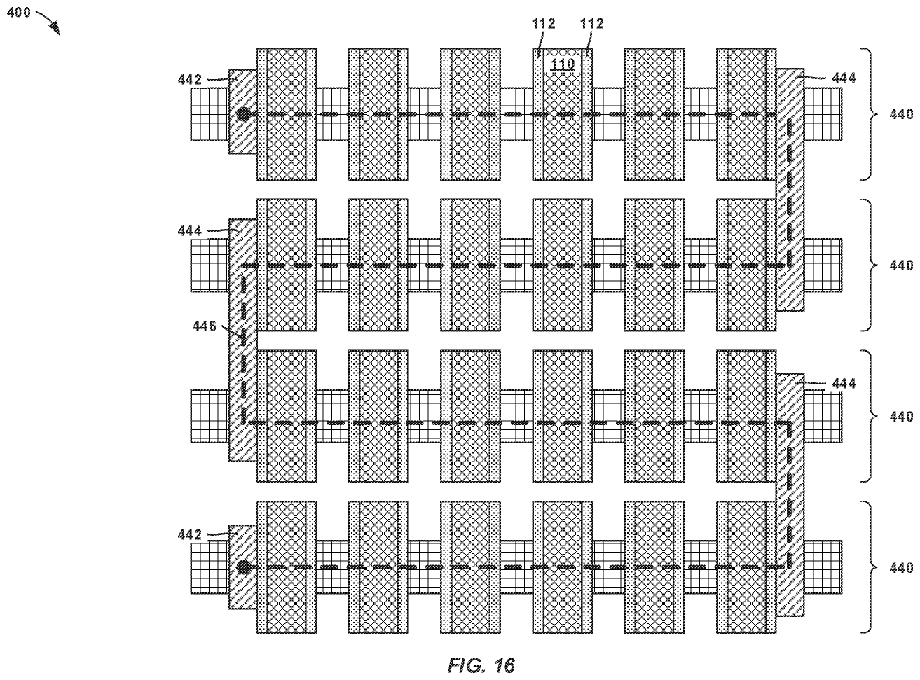

Referring now to FIG. 16, a structure 400 is shown. The structure 400 represents a stacked long channel transistor structure according to an alternative embodiment. FIG. 16 is a representative illustration of a top view of the structure 400 omitting some features as described above with reference to FIG. 1. The structure 400 is substantially similar to the structure 100 described above; however, the structure 400 is arranged in an alternate configuration.

For purposes of the present description, the structure 400 is illustrated and described with four transistor arrays 440 arranged adjacent to one another. Other configurations including additional transistor arrays stacked on top of the four transistor arrays 440 are explicitly contemplated. Like the structure 100, the structure 400 also includes a source drain contacts 442 and horizontal strap interconnects 444.

Critical to the present embodiment, the horizontal strap interconnects 444 form electrical connections between ends of adjacent transistor arrays 440 in a similar manner as described above with respect to the structure 100. Similarly, the source drain contacts 442 provide external electrical connections to the structure 400, also similar to the first source drain contact 128 and the second source drain contact 130 described above.

Like the structure 100, the structure 400 also has a continuous channel path 446 that begins at the one of the source drain contact 442 and ends at the other source drain contact 442, or vice versa. The individual transistor structures of the illustrated embodiment are essentially wired in series to produce the continuous channel path 446.

In sum, the cumulative channel length of the structure 400 is 24 times the channel length of any one individual transistor structure. Unlike conventional structures, the 24 individual transistor structures of the four transistor arrays are wired together and operate as a single long channel device.

For reference purposes measurements taken in the x-direction, perpendicular to the gate conductors 110, are herein referred to as “length”, while measurements taken in the y-direction, parallel to the gate conductors 110, are herein referred to as “width”.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A long channel transistor structure comprising:
a first transistor array adjacent to a second transistor array;
a third transistor array adjacent to a fourth transistor array, wherein the third transistor array and the fourth transistor array are arranged above the first transistor array and the second transistor array; and
a continuous channel path through channels of the first transistor array, the second transistor array, the third transistor array, and the fourth transistor array.

2. The long channel transistor structure according to claim 1, further comprising:
a common gate electrically connected to all individual gates of the first transistor array, the second transistor array, the third transistor array, and the fourth transistor array.

3. The long channel transistor structure according to claim 1, further comprising:
a first source drain contact arranged at one end of the continuous channel path; and
a second source drain contact arranged at the other end of the continuous channel path.

4. The long channel transistor structure according to claim 3,
wherein the first source drain contact is self-aligned to an end-most gate spacer of the third transistor array; and
wherein the second source drain contact is self-aligned to an end-most gate spacer of the fourth transistor array.

5. The long channel transistor structure according to claim 1, wherein the continuous channel path comprises:
a first electrical connection between the channel of the first transistor array and the channel of the third transistor array,
a second electrical connection between the channel of the first transistor array and the channel of the second transistor array, and
a third electrical connection between the channel of the second transistor array and the channel of the fourth transistor array.

6. The long channel transistor structure according to claim 5,
wherein the first electrical connection extends from a fin of the first transistor array to a fin of the third transistor array,
wherein the third electrical connection extends from a fin of the second transistor array and the fourth transistor array.

7. The long channel transistor structure according to claim 5,
wherein the first electrical connection and the second electrical connection are arranged at opposite ends of the first transistor array; and
wherein the second electrical connection and the third electrical connection are arranged at opposite ends of the second transistor array.

8. A long channel transistor structure comprising:
a first transistor array adjacent to a second transistor array;
a third transistor array adjacent to a fourth transistor array, wherein the third transistor array and the fourth transistor array are arranged above the first transistor array and the second transistor array; and
interconnect structures forming a continuous electrical path through channels of the first transistor array, the second transistor array, the third transistor array, and the fourth transistor array.

9. The long channel transistor structure according to claim 8, further comprising:
a common gate electrically connected to all individual gates of the first transistor array, the second transistor array, the third transistor array, and the fourth transistor array.

10. The long channel transistor structure according to claim 8, further comprising:
a first source drain contact arranged at one end of the continuous electrical path; and
a second source drain contact arranged at the other end of the continuous electrical path.

11. The long channel transistor structure according to claim 10,
wherein the first source drain contact is self-aligned to an end-most gate spacer of the third transistor array; and
wherein the second source drain contact is self-aligned to an end-most gate spacer of the fourth transistor array.

12. The long channel transistor structure according to claim 8, wherein the interconnect structures comprise:
a first electrical connection between the channel of the first transistor array and the channel of the third transistor array,
a second electrical connection between the channel of the first transistor array and the channel of the second transistor array, and
a third electrical connection between the channel of the second transistor array and the channel of the fourth transistor array.

13. The long channel transistor structure according to claim 12,
wherein the first electrical connection and the second electrical connection are arranged at opposite ends of the first transistor array; and
wherein the second electrical connection and the third electrical connection are arranged at opposite ends of the second transistor array.

14. A long channel transistor structure comprising:
a first transistor array comprising a first series of short channel devices and a first continuous channel;
a second transistor array comprising a second series of short channel devices and a second continuous channel; and
a vertical interconnect structure electrically connecting the first continuous channel to the second continuous channel.

15. The long channel transistor structure according to claim 14, further comprising:
a common gate shared by the first series of short channel devices and the second series of short channel devices.

16. The long channel transistor structure according to claim 14, wherein the vertical interconnect structure is self-aligned to an end-most gate spacers of each of the first transistor array and the second transistor array.

17. The long channel transistor structure according to claim 14, further comprising:
a first source drain contact arranged at one end of the first transistor array opposite the vertical interconnect structure; and
a second source drain contact arranged at the other end of the second transistor array opposite the vertical interconnect structure.

18. The long channel transistor structure according to claim 17,
wherein the first source drain contact is self-aligned to an end-most gate spacer of the first transistor array; and
wherein the second source drain contact is self-aligned to an end-most gate spacer of the second transistor array.

19. The long channel transistor structure according to claim 14, wherein the vertical interconnect structure comprises:
an electrical connection between a first channel of the first transistor array and a second channel of the second transistor array.

20. The long channel transistor structure according to claim 19,
wherein the first electrical connection and the second electrical connection are arranged at opposite ends of the first transistor array; and
wherein the second electrical connection and the third electrical connection are arranged at opposite ends of the second transistor array.
